(19) United States
(12) Patent Application Publication
(10) Pub. No.: US 2026/0068555 A1
(43) Pub. Date: Mar. 5, 2026

(54) ELECTROSTATIC CLAMPING OF GLASS SUBSTRATES

(71) Applicant: Applied Materials, Inc., Santa Clara, CA (US)

(72) Inventors: Andrew M. Waite, Beverly, MA (US); Michael W. Osborne, Clinton, MA (US)

(21) Appl. No.: 18/825,623

(22) Filed: Sep. 5, 2024

(51) Int. Cl. H01L 21/3205; H01L 21/3215; H01L 21/683; H01L 29/66

(52) U.S. Cl. CPC H10P 14/416; H10D 30/0321; H10P 32/302; H10P 72/72

(57) ABSTRACT

Methods of electrostatically clamping a glass substrate to a platen are disclosed. In one embodiment, a conductive layer is applied to the glass substrate, wherein the conductive layer provides the requisite clamping force. The transistor is then fabricated on the glass substrate. The conductive layer may be transparent, such that the bottom surface of the transistor may be inspected. In another embodiment, a lower polysilicon layer and oxide layer are deposited on the glass substrate. The transistor is then fabricated above the oxide layer.

### FIELD

Embodiments of the present disclosure relate to methods to electrostatically clamp a glass substrate used for thin film transistor fabrication to a platen.

### BACKGROUND

Semiconductor devices are fabricated using a plurality of processes, including etching, implanting, and amorphization. In some of these processes, the workpiece may be disposed on a platen, which provides an electrostatic force so as to clamp the workpiece in place. This electrostatic force is generated by electrodes disposed in the platen, which are energized in a specific sequence to provide the clamping force. This clamping also relies on a workpiece that is conductive, and a dielectric layer between the electrodes and the workpiece.

In many embodiments, silicon wafers are used as the workpiece. The thickness and conductivity of the silicon wafers is sufficient to achieve the desired clamping force. More recently, thinner workpieces have been used. In certain embodiments, the workpiece comprises a polysilicon layer deposited on a glass substrate. Glass is not conductive, so the electrostatic clamping relies on the polysilicon layer disposed on the glass. As this polysilicon layer gets thinner, the amount of clamping force that can be generated is reduced.

Further, in certain embodiments, this polysilicon layer is patterned during the fabrication process. This further reduces the clamping force that may be achieved.

Therefore, a method that allows these thinner substrates to be adequately clamped using an electrostatic platen would be beneficial.

### SUMMARY

Methods of electrostatically clamping a glass substrate to a platen are disclosed. In one embodiment, a conductive layer is applied to the glass substrate, wherein the conductive layer provides the requisite clamping force. The transistor is then fabricated on the glass substrate. The conductive layer may be transparent, such that the bottom surface of the transistor may be inspected. In another embodiment, a lower polysilicon layer and oxide layer are deposited on the glass substrate. The transistor is then fabricated above the oxide layer.

According to one embodiment, a method of fabricating a semiconductor device is disclosed. The method comprises applying a conductive layer to a top surface of a glass substrate, the top surface opposite a bottom surface of the glass substrate; positioning a polysilicon layer above the conductive layer; electrostatically clamping the bottom surface of the glass substrate to a clamping surface of a platen, wherein the conductive layer enables the electrostatically clamping operation to provide sufficient clamping force to clamp the glass substrate; and performing an ion implantation to form doped regions in the polysilicon layer. In some embodiments, the conductive layer is transparent at visible light frequencies or ultraviolet frequencies. In certain embodiments, the conductive layer comprises indium tin oxide, doped anatase or doped zinc oxide. In some embodiments, the conductive layer has a thickness of between 0.5 μm and 1.5 μm. In some embodiments, one or more intermediate layers are disposed on the conductive layer before the polysilicon layer is positioned. In some embodiments, the semiconductor device comprises a transistor device, and the method further comprises: forming a gate structure of the transistor device on top of the polysilicon layer, wherein the gate structure includes a gate electrode disposed on a gate dielectric layer; and wherein the doped regions comprise source and drain regions of the transistor device.

According to another embodiment, a method of fabricating a semiconductor device is disclosed. The method comprises applying a conductive layer to a bottom surface of a glass substrate; positioning a polysilicon layer above a top surface of the glass substrate; electrostatically clamping the bottom surface of the glass substrate to a clamping surface of a platen, wherein the conductive layer enables the electrostatically clamping operation to provide sufficient clamping force to clamp the glass substrate; and performing an ion implantation to form doped regions in the polysilicon layer. In some embodiments, the conductive layer is transparent at visible light frequencies or ultraviolet frequencies. In certain embodiments, the conductive layer comprises indium tin oxide, doped anatase or doped zinc oxide. In some embodiments, the conductive layer has a thickness of between 0.5 μm and 1.5 μm. In some embodiments, one or more intermediate layers are disposed on the glass substrate before the polysilicon layer is positioned. In some embodiments, the semiconductor device comprises a transistor device, and the method further comprises: forming a gate structure of the transistor device on top of the polysilicon layer, wherein the gate structure includes a gate electrode disposed on a gate dielectric layer; and wherein the doped regions comprise source and drain regions of the transistor device.

According to another embodiment, a method of fabricating a semiconductor device is disclosed. The method comprises positioning a lower polysilicon layer and an oxide layer above a top surface of a glass substrate; depositing a polysilicon layer on top of the oxide layer; electrostatically clamping a bottom surface of the glass substrate to a clamping surface of a platen, wherein the lower polysilicon layer enables the electrostatically clamping operation to provide sufficient clamping force to clamp the glass substrate; and performing an ion implantation to form doped regions in the polysilicon layer. In some embodiments, the lower polysilicon layer is deposited using chemical vapor deposition or plasma enhanced chemical vapor deposition. In certain embodiments, a doping gas is introduced during the chemical vapor deposition or plasma enhanced chemical vapor deposition so as to increase a conductivity of the lower polysilicon layer. In some embodiments, the lower polysilicon layer has a thickness of between 500 nm and 10 μm. In some embodiments, the oxide layer comprises silicon dioxide. In some embodiments, the oxide layer has a thickness of between 500 nm and 1 μm. In some embodiments, one or more intermediate layers are disposed on the top surface of the glass substrate before the lower polysilicon layer and the oxide layer are positioned. In some embodiments, the semiconductor device comprises a transistor device, and the method further comprises: forming a gate structure of the transistor device on top of the polysilicon layer, wherein the gate structure includes a gate electrode disposed on a gate dielectric layer; and wherein the doped regions comprise source and drain regions of the transistor device.

### BRIEF DESCRIPTION OF THE FIGURES

For a better understanding of the present disclosure, reference is made to the accompanying drawings, which are incorporated herein by reference and in which:

FIG. 1 shows a sequence to fabricate a thin film device according to a first embodiment;

FIGS. 2A-2I show cross-sections of the device during the execution of the sequence of FIG. 1;

FIG. 3 shows a sequence to fabricate a thin film device according to a second embodiment; and

FIGS. 4A-4J show cross-sections of the device during the execution of the sequence of FIG. 3.

### DETAILED DESCRIPTION

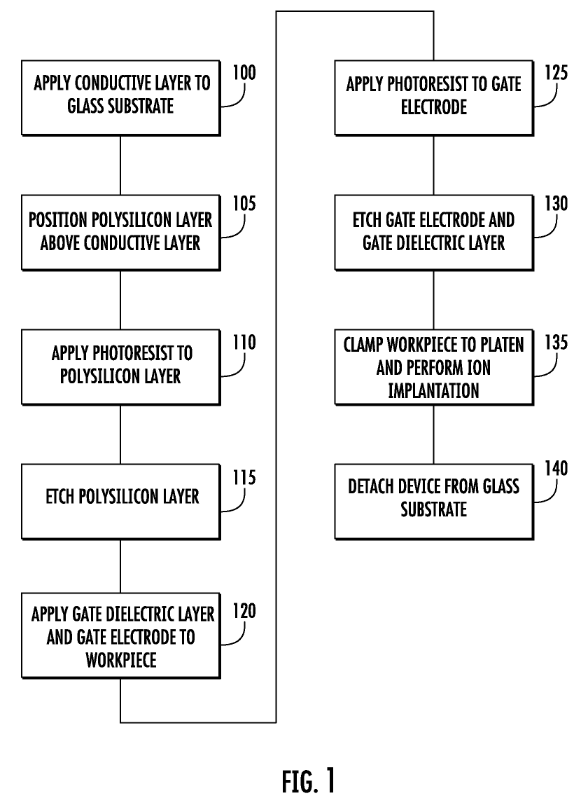

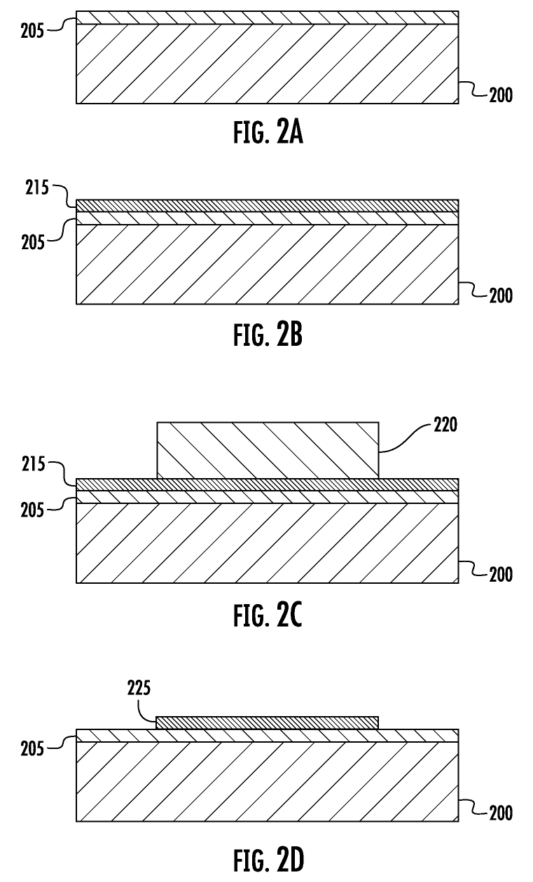

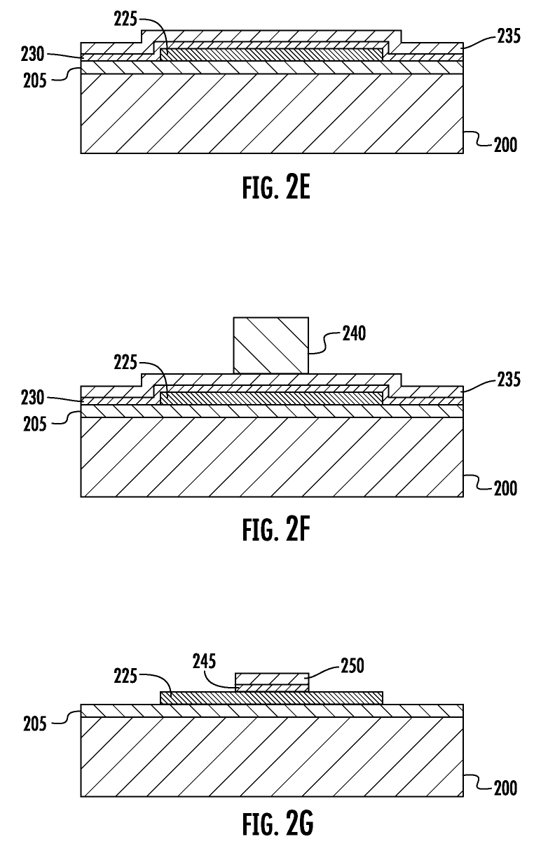

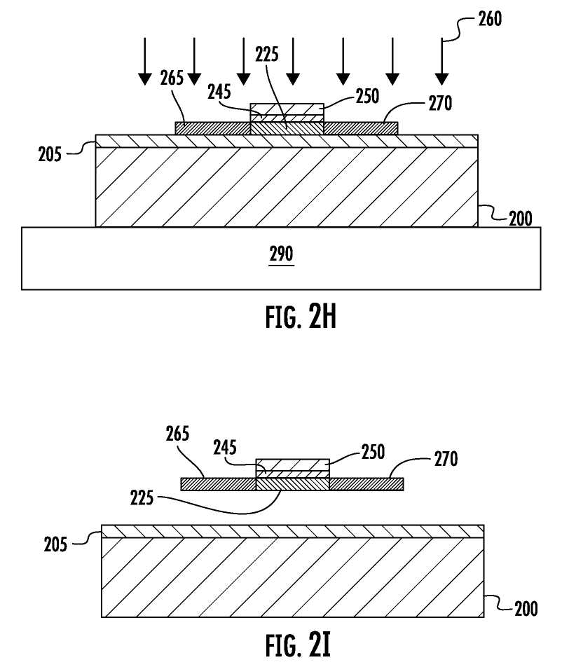

As noted above, the electrostatic clamping of thin film workpieces may be problematic. FIG. 1 shows a sequence that may be used to provide adequate electrostatic clamping force while enabling the fabrication of thin film transistors. FIGS. 2A-2I show cross-sections of the workpiece during the execution of this sequence.

First, as shown in Box 100 and in FIG. 2A, a conductive layer 205 is applied to the top surface of a glass substrate 200. In some embodiments, the conductive layer 205 may be applied using sputtering from a solid source. The conductive layer 205 may cover the entirety of the top surface of the glass substrate 200, or may cover less than the entire top surface. In some embodiments, the conductive layer 205 may be transparent to allow inspection of the bottom surface of the fabricated transistor device. For example, the conductive layer 205 may be transparent at visible light frequencies or ultraviolet frequencies. In certain embodiments, the conductive layer 205 may be made using indium tin oxide (ITO), doped anatase (TiO₂), doped zinc oxide or another suitable conductive material. In some embodiments, the thickness of the conductive layer 205 may be between 0.5 μm and 1.5 μm.

Next, as shown in Box 105 and FIG. 2B, a polysilicon layer 215 is positioned above the conductive layer 205. In certain embodiments, one or more intermediate layers may be disposed between the conductive layer 205 and the polysilicon layer 215. These intermediate layers may be useful for detaching the glass substrate 200 from the polysilicon layer 215. The polysilicon layer 215 may be deposited directly on the conductive layer 205 or, if intermediate layers are included, on the top of the topmost intermediate layer, such as by chemical vapor deposition or plasma enhanced chemical vapor deposition. This polysilicon layer 215 may have a thickness of between 35 nm and 100nm. The polysilicon layer 215 will later be subjected to ion implantation to form the source and drain regions.

A photoresist 220 is then selectively applied to the polysilicon layer 215, as shown in Box 110 and FIG. 2C. As shown in Box 115 and FIG. 2D, the polysilicon layer 215 is then selectively patterned. This may be done using a dry etch process, such as a hydrogen bromide (HBr) based chemistry, or using a wet etch process. This patterned polysilicon region 225 forms the active region of the transistor device being fabricated. The photoresist 220 is then stripped.

Next, as shown in Box 120 and FIG. 2E, the gate dielectric layer 230 and the gate electrode 235 are applied on top of the workpiece. The gate dielectric layer 230 may be any suitable dielectric material, such as silicon dioxide, silicon nitride, hafnium oxide, aluminum oxide or a stack of two or more of these materials. Additionally, the gate electrode 235 may be a conductive material such as doped polysilicon. These layers may be applied using chemical vapor deposition (CVD), plasma enhanced chemical vapor deposition (PECVD) or another suitable technique. More particularly, the gate electrode 235 may be in-situ doped during deposition. The gate dielectric layer 230 may be between 1 nm and 10nm thick, while the gate electrode 235 may be between 100 nm and 500 nm thick.

As shown in Box 125 and FIG. 2F, a second photoresist 240 is applied on top of the selected portions of the gate electrode 235. The selected portions may be the portions directly above the patterned polysilicon region 225. Next, the gate electrode 235 and the gate dielectric layer 230 are then selectively etched such as by a HBr dry etch process, as shown in Box 130 and FIG. 2G to form the patterned gate dielectric layer 245 and the patterned gate electrode 250, which are disposed on the patterned polysilicon region 225. The second photoresist 240 is then stripped.

At this point, the gate structure of the transistor has been created. In other words, Boxes 105-130 are performed to create the gate structure of the transistor. Further, there may be modifications to this sequence. For example, in some embodiments, the polysilicon layer 215 may not be patterned. Thus, in these embodiments, Boxes 110-115 and FIGS. 2C-2D may be omitted.

After formation of the gate structure, the source and drain regions may be added. This is typically done via ion implantation, as shown in Box 135 and FIG. 2H. Thus, prior to creating these regions, the bottom surface of the glass substrate 200 is electrostatically clamped to a clamping surface of the platen 290. As noted above, the glass substrate 200 is not conductive. However, due to the presence of the conductive layer 205, sufficient clamping force may be generated. After electrostatically clamping the workpiece to the platen 290, ion implantation 260 is performed. The species used for the implantation may be a dopant species, such as boron, phosphorus, or another suitable species. Note that the workpiece may be electrostatically clamped to the platen 290 at an earlier point in the sequence if desired.

Next, after the formation of the drain region 265 and source region 270, the workpiece may be removed from the platen 290. The glass substrate 200 is then detached from the device, as shown in Box 140 and FIG. 2I. This may be done in a variety of different ways, such as by using thermal, chemical, mechanical or radiation processes.

The transistor device may now be subjected to back end of line (BEoL) processes, as is well known in the art. In other embodiments, the BEoL processes may be performed while the device is still attached to the glass substrate 200 (before Box 140 is performed).

Thus, by the introduction of the transparent conductive layer to the glass substrate 200, the workpiece is able to be electrostatically clamped to the platen 290, even if the polysilicon layer 215 is very thin or patterned. Note that while this sequence describes the conductive layer 205 being deposited on the top surface of the glass substrate 200, other embodiments are possible. For example, in a different embodiment, the conductive layer 205 may be disposed on the bottom surface of the glass substrate 200. In this embodiment, the polysilicon layer 215 is deposited directly on the top surface of the glass substrate 200 or on the topmost intermediate layer. In all of these embodiments, the conductive layer 205 may be transparent to allow inspection of the bottom of the transistor device. For example, the conductive layer 205 may be transparent at visible light frequencies or ultraviolet frequencies.

Note that while FIG. 1 and FIGs 2A-2 describe the process of fabricating a transistor device, this technique may be applied to any semiconductor structure formed on a glass substrate 200 that uses ion implantation during the fabrication process. Specifically, the conductive layer 205 is applied to the glass substrate 200 and a polysilicon layer 215 is positioned above the conductive layer 205, either directly on the conductive layer 205 or on an intermediate layer. Then, optionally, one or more process steps may be performed on the polysilicon layer 215. Afterwards, the glass substrate 200 is electrostatically clamped and an ion implantation process is performed to create doped regions in the polysilicon layer 215. As described above, the fabricated device may be separated from the glass substrate 200 by applying thermal, chemical, mechanical or radiation processes.

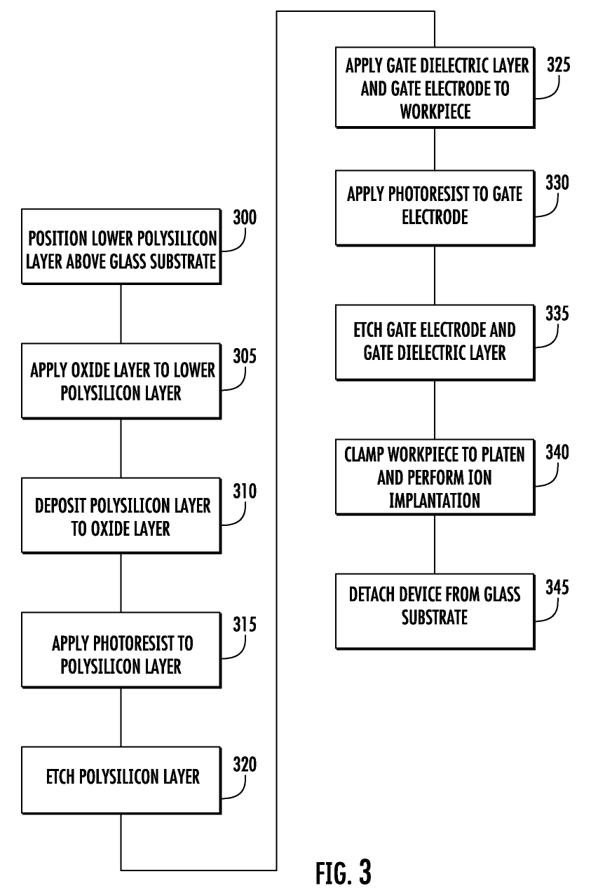

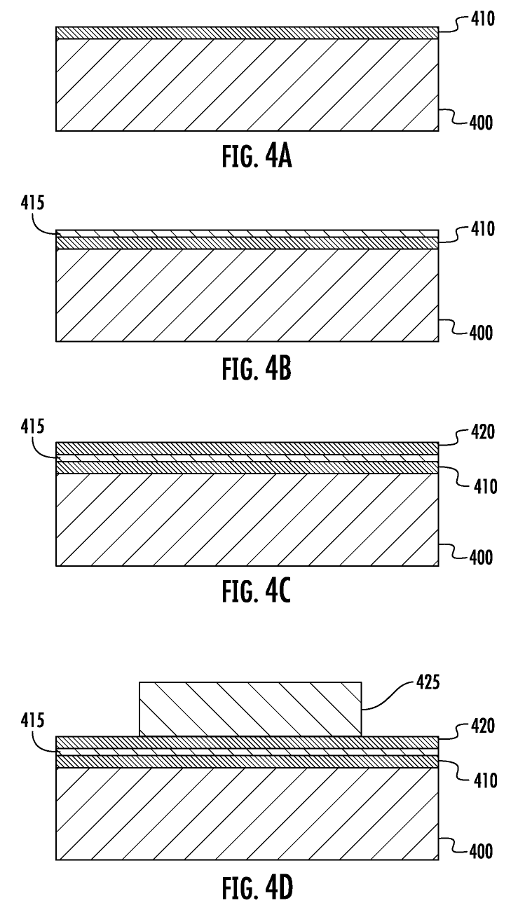

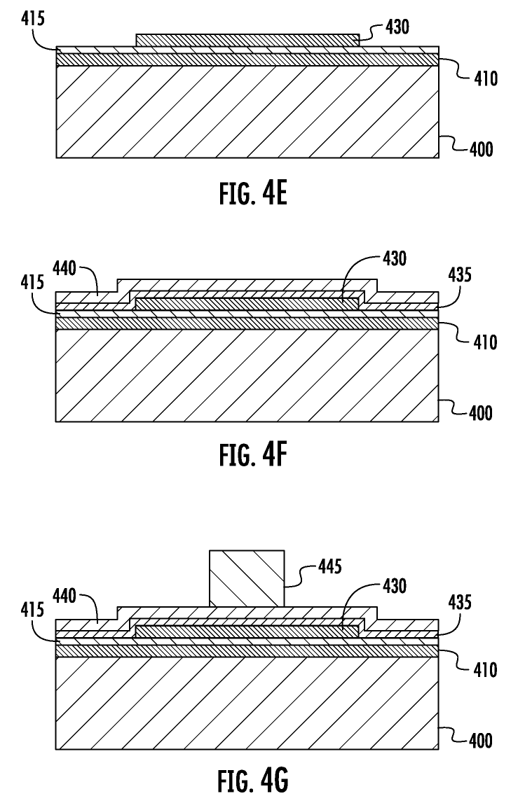

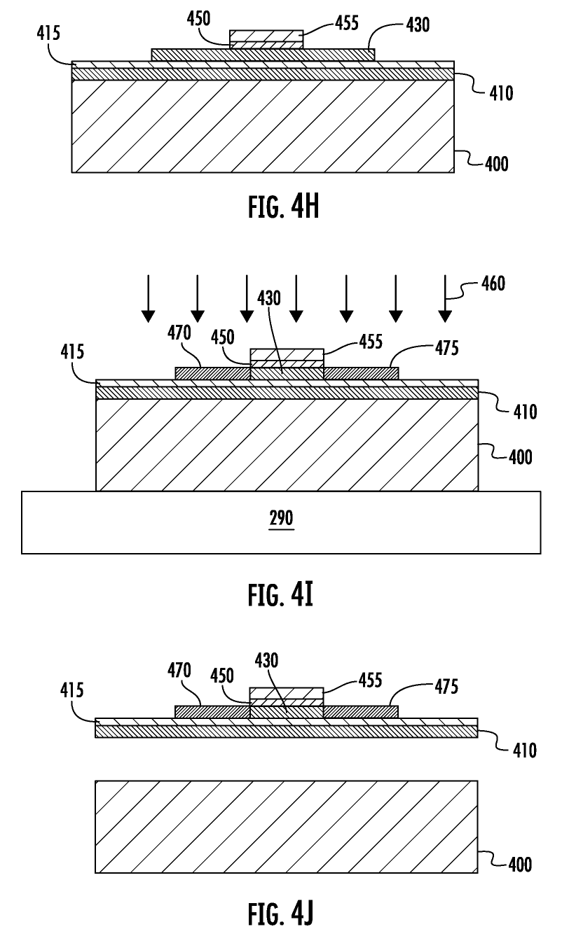

FIG. 3 shows a second sequence that may be used to create a thin film transistor with adequate clamping force. This sequence does not rely on the conductive layer 205 described above. Rather, this sequence relies on the inclusion of a lower polysilicon layer to provide the requisite clamping force. First, as shown in Box 300 and FIG. 4A, a lower polysilicon layer 410 is positioned above the glass substrate 400. In some embodiments, there may be one or more intermediate layers between the glass substrate 400 and the lower polysilicon layer 410. These intermediate layers may be useful for detaching the glass substrate 400 from the lower polysilicon layer 410. In some embodiments, this lower polysilicon layer 410 may be relatively thick, such as between 500 nm and 10 μm thick. This lower polysilicon layer 410 may be applied to the glass substrate 400 or the topmost intermediate layer using deposition, or another suitable method. In some embodiments, this lower polysilicon layer 410 may be in-situ doped by the addition of a doping species during deposition. Alternatively, this lower polysilicon layer 410 may be doped by means of ion implantation and anneal. This doping may increase the conductivity of the lower polysilicon layer 410.

Next as shown in Box 305 and FIG. 4B, an oxide layer 415 is applied on top of the lower polysilicon layer 410. This oxide may be silicon dioxide or another oxide. This oxide layer 415 serves as an etch stop for future processes and may be between 500 nm and 1 μm thick. This oxide layer 415 may be deposited using chemical vapor deposition or plasma enhanced chemical vapor deposition.

The polysilicon layer 420 is then deposited on top of the oxide layer 415, such as by chemical vapor deposition or plasma enhanced chemical vapor deposition, as shown in Box 310 and FIG. 4C. This polysilicon layer 420 may have a thickness of between 35 nm and 100nm. This polysilicon layer 420 will later be subjected to ion implantation to form the source and drain regions.

A photoresist 425 is then selectively applied to the polysilicon layer 420, as shown in Box 315 and FIG. 4D. As shown in Box 320 and FIG. 4E, the polysilicon layer 420 is then selectively patterned. The etch process uses a technique that is highly selective to polysilicon but does not etch the oxide layer 415. For example, a dry etch using a HBr based chemistry may be used. This patterned polysilicon region 430 forms the active region of the transistor device being fabricated. The photoresist 425 is then stripped.

Next, as shown in Box 325 and FIG. 4F, the gate dielectric layer 435 and the gate electrode 440 are applied on top of the workpiece. The gate dielectric layer 435 may be any suitable dielectric material, such as silicon dioxide, silicon nitride, hafnium oxide, aluminum oxide or a stack of two or more of these materials. Additionally, the gate electrode 440 may be a conductive material, such as doped polysilicon. These layers may be applied using chemical vapor deposition, plasma enhanced chemical vapor deposition or another suitable technique. More particularly, the gate electrode 440 may be in-situ doped during deposition. The gate dielectric layer 435 may be between 1 nm and 10nm thick, while the gate electrode 440 may be between 100 nm and 500 nm thick.

As shown in Box 330 and FIG. 4G, a second photoresist 445 is applied on top of the selected portions of the gate electrode 440. The selected portions may be the portions directly above the patterned polysilicon region 430. Next, the gate electrode 440 and the gate dielectric layer 435 are then selectively etched such as by a HBr dry etch process, as shown in Box 335 and FIG. 4H, to form the patterned gate dielectric layer 450 and the patterned gate electrode 455, which are disposed on the patterned polysilicon region 430. The second photoresist 445 is then stripped.

At this point, the gate structure of the transistor has been created. In other words, Boxes 310-335 are performed to create the gate structure of the transistor. Further, there may be modifications to this sequence. For example, in some embodiments, the polysilicon layer 420 may not be patterned. Thus, in these embodiments, Boxes 315-320 and FIGS. 4D-4E may be omitted.

After formation of the gate structure, the source and drain regions may be added. This is typically done via ion implantation, as shown in Box 340 and FIG. 4I. Thus, prior to creating these regions, the bottom surface of the glass substrate 440 is electrostatically clamped to the clamping surface of a platen 290. As noted above, the glass substrate 400 is not conductive. However, due to the presence of the lower polysilicon layer 410, sufficient clamping force may be generated. After electrostatically clamping the workpiece to the platen 290, ion implantation 460 is performed. The species used for the implantation may be a dopant species, such as boron, phosphorus, or another suitable species. Note that the workpiece may be electrostatically clamped to the platen 290 at an earlier point in the sequence if desired.

Next, after the formation of the drain region 470 and source region 475, the workpiece may be removed from the platen 290. The glass substrate 400 is then detached from the transistor device, as shown in Box 345 and FIG. 4J. This may be done by applying thermal, chemical, mechanical or radiation processes.

The transistor device may now be subjected to back end of line (BEoL) processes, as is well known. In other embodiments, the BEoL processes may be performed while the device is still attached to the glass substrate 400 (before Box 345 is performed).

Note that while the disclosure described the process of fabricating a transistor device, this technique may be applied to any semiconductor structure formed on a glass substrate that uses ion implantation during the fabrication process. Specifically, the lower polysilicon layer 410 and the oxide layer 415 are positioned on the glass substrate 400. As noted above, in certain embodiments, there may be one or more intermediate layers between the glass substrate 400 and the lower polysilicon layer 410 to facilitate the detachment of the glass substrate. A polysilicon layer 420 is then formed on the oxide layer 415. Then, optionally, one or more process steps may be performed on the polysilicon layer 420. Afterwards, the glass substrate 400 is electrostatically clamped and an ion implantation process is performed to create doped regions in the polysilicon layer 420. As described above, the fabricated device is detached from the glass substrate 400 by applying thermal, chemical, mechanical or radiation processes.

The system and method described herein have many advantages. As workpieces become thinner, new ways to allow electrostatic clamping of those workpieces to platens are desirable. In the first embodiment, the introduction of a conductive layer, deposited directly on the glass substrate, allows the glass substrate to be electrostatically clamped, without mandating any other changes to the fabrication process. In the second embodiment, the addition of a thicker lower polysilicon layer provides the structure to facilitate electrostatic clamping, while employing materials that are already part of the fabrication process.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A method of fabricating a semiconductor device, comprising:
applying a conductive layer to a top surface of a glass substrate, the top surface opposite a bottom surface of the glass substrate;
positioning a polysilicon layer above the conductive layer;
electrostatically clamping the bottom surface of the glass substrate to a clamping surface of a platen, wherein the conductive layer enables the electrostatically clamping operation to provide sufficient clamping force to clamp the glass substrate; and
performing an ion implantation to form doped regions in the polysilicon layer.

2. The method of claim 1, wherein the conductive layer is transparent at visible light frequencies or ultraviolet frequencies.

3. The method of claim 2, wherein the conductive layer comprises indium tin oxide, doped anatase or doped zinc oxide.

4. The method of claim 1, wherein the conductive layer has a thickness of between 0.5 μm and 1.5 μm.

5. The method of claim 1, further comprising disposing one or more intermediate layers on the conductive layer before the polysilicon layer is positioned.

6. The method of claim 1, wherein the semiconductor device comprises a transistor device, and the method further comprises:
forming a gate structure of the transistor device on top of the polysilicon layer, wherein the gate structure includes a gate electrode disposed on a gate dielectric layer; and
wherein the doped regions comprise source and drain regions of the transistor device.

7. A method of fabricating a semiconductor device, comprising:
applying a conductive layer to a bottom surface of a glass substrate;
positioning a polysilicon layer above a top surface of the glass substrate;
electrostatically clamping the bottom surface of the glass substrate to a clamping surface of a platen, wherein the conductive layer enables the electrostatically clamping operation to provide sufficient clamping force to clamp the glass substrate; and
performing an ion implantation to form doped regions in the polysilicon layer.

8. The method of claim 7, wherein the conductive layer is transparent at visible light frequencies or ultraviolet frequencies.

9. The method of claim 8, wherein the conductive layer comprises indium tin oxide, doped anatase or doped zinc oxide.

10. The method of claim 7, wherein the conductive layer has a thickness of between 0.5 μm and 1.5 μm.

11. The method of claim 7, further comprising disposing one or more intermediate layers on the top surface of the glass substrate before the polysilicon layer is positioned.

12. The method of claim 7, wherein the semiconductor device comprises a transistor device, and the method further comprises:
forming a gate structure of the transistor device on top of the polysilicon layer, wherein the gate structure includes a gate electrode disposed on a gate dielectric layer; and
wherein the doped regions comprise source and drain regions of the transistor device.

13. A method of fabricating a semiconductor device, comprising:
positioning a lower polysilicon layer and an oxide layer above a top surface of a glass substrate;
depositing a polysilicon layer on top of the oxide layer;
electrostatically clamping a bottom surface of the glass substrate to a clamping surface of a platen, wherein the lower polysilicon layer enables the electrostatically clamping operation to provide sufficient clamping force to clamp the glass substrate; and
performing an ion implantation to form doped regions in the polysilicon layer.

14. The method of claim 13, wherein the lower polysilicon layer is deposited using chemical vapor deposition or plasma enhanced chemical vapor deposition.

15. The method of claim 14, wherein a doping gas is introduced during the chemical vapor deposition or plasma enhanced chemical vapor deposition so as to increase a conductivity of the lower polysilicon layer.

16. The method of claim 13, wherein the lower polysilicon layer has a thickness of between 500 nm and 10 μm.

17. The method of claim 13, wherein the oxide layer comprises silicon dioxide.

18. The method of claim 13, wherein the oxide layer has a thickness of between 500 nm and 1 μm.

19. The method of claim 13, further comprising disposing one or more intermediate layers on the top surface of the glass substrate before the lower polysilicon layer and the oxide layer are positioned.

20. The method of claim 13, wherein the semiconductor device comprises a transistor device, and the method further comprises:
forming a gate structure of the transistor device on top of the polysilicon layer, wherein the gate structure includes a gate electrode disposed on a gate dielectric layer; and
wherein the doped regions comprise source and drain regions of the transistor device.
